(19) United States
(12) Patent Application Publication
(10) Pub. No.: US 2019/0094912 A1
(43) Pub. Date: Mar. 28, 2019

(54) SIMPLIFIED SHOCK ISOLATION SYSTEM

(71) Applicant: Benjamin K. Sharfi, Rancho Cucamonga, CA (US)

(72) Inventor: Benjamin K. Sharfi, Rancho Cucamonga, CA (US)

(21) Appl. No.: 15/716,065

(22) Filed: Sep. 26, 2017

(51) Int. Cl. G06F 1/16; G06F 1/20; H05K 7/20

(52) U.S. Cl. CPC G06F 1/1656; H05K 7/2039; G06F 1/203

(57) ABSTRACT

An assembly for electrical devices that will protect the devices from G force trauma and overheating. The assembly protects the device through the use of a shock absorbing layer with thermal conductive qualities, a rigid base and a fastener assembly.

### FIELD OF INVENTION

The present invention relates to a shock protection system for electronic devices that includes a rigid base, a polyurethane foam gasket, a thermal conductive layer and a fastener and fastening sleeves.

### BACKGROUND OF THE INVENTION

Electronic devices in general, and computers in specific, are becoming increasingly compact and small in size. At the same time that they are getting smaller, they are also getting more powerful, in that they are capable of storing more information and processing data at greater speeds. One result of these two trends is that protecting the devices from shock trauma caused by high G falls, and properly dissipating the resultant heat, is becoming more difficult and more important.

If the device is not properly protected from the fall, the device risks complete electrical device destruction. The physical jostling of the electrical device can cause shortages due to the violence of the trauma. Additionally, even if the devices are not individually damaged by the trauma, there is the possibility that the devices have been displaced and the displacement may cause the device to either work slower, not in its intended manner, or not at all.

If the heat is not sufficiently removed from an electronic device, then the build-up of heat within the device tends to have adverse effects. One adverse effect is that the device may tend to run more slowly. Another adverse effect is that the device may become damaged by attaining a temperature at which various devices start to fail. Even if devices don't fail, the time spent at an increased temperature tends to reduce the viable lifetime of many electronic devices. Because of this, a great deal of attention has been paid to various methods by which electronics can be cooled.

However, many of these methods are not effective when the electronic device is disposed in an environment that is not particularly well-suited for such electronics. For example, when the environment is hotter, wetter, dustier, dirtier, or subjected to more vibration, shock, or rough handling than a typical office setting, additional cooling challenges are introduced. For example, electronic devices protected from such environments by being placed within ruggedized housings can be very difficult to cool, because the cooling system cannot compromise the integrity of the ruggedized housing that is protecting the electronic device from the environment.

This patent is designed to maximize the protection of the electronic devices from shock trauma without leaving it vulnerable to overheating.

### SUMMARY OF INVENTION

The present invention comprises an assembly intended to enable an electrical device to withstand high G's of instantaneous acceleration without degradation, failure or electronic shorting. The assembly positions a rigid base, such as a heatsink, onto a electrical device. The rigid base and the electrical device are separated by a shock absorbing layer.

The shock absorbing layer is made of a peripheral gasket made of polyurethane foam and a thermal conductive layer. The thermal conductive layer is located within the periphery of the peripheral gasket and is completely surrounded by the peripheral gasket. The thermal conductive layer may be placed in several arrangements, including rectangles or strips. The rectangles or strips do not abut in order to allow for expansion of the material upon application of compression. Similarly, the thermal conductive layer and the gasket do not abut for the same reason. The thermal-conductive material provides both thermal conductivity and additional shock absorption.

The device to be protected is fastened to the rigid base by means of fastening sleeves which permit slight deformation in compression and shear when force is applied, but also allow for the fastening sleeves to return to their original dimensions after the force is removed.

### BRIEF DESCRIPTION OF THE DRAWINGS

FIG. 1 is a side view of one embodiment of the invention.

FIG. 2 is an exploded side view of an embodiment of the invention shown in FIG. 1.

FIG. 3 is a top view of the shock absorbing layer in one embodiment of the invention.

FIG. 4 is a perspective view of the assembly with the fastener exploded in one embodiment of the invention.

FIG. 5 is a close up perspective view of the exploded fastener assembly in one embodiment of the invention.

FIG. 6 is a close up perspective view of the completed fastener assembly in one embodiment of the invention.

FIG. 7 is two views of the sleeve of one embodiment of the invention.

### DETAILED DESCRIPTION OF THE INVENTION

While the present invention will be described more fully hereinafter, it is to be understood at the outset of the description which follows that persons of skill in the appropriate arts may modify the invention herein described while still achieving the favorable results of this invention. Accordingly, the description which follows is to be understood as being a broad, teaching disclosure directed to persons of skill in the appropriate arts, and not as limiting upon the present invention.

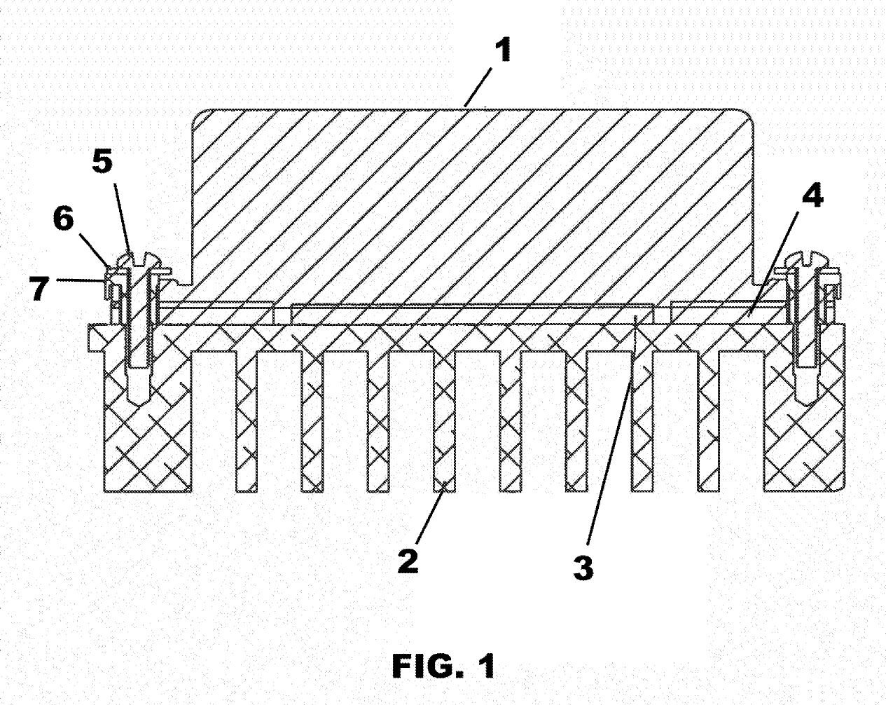

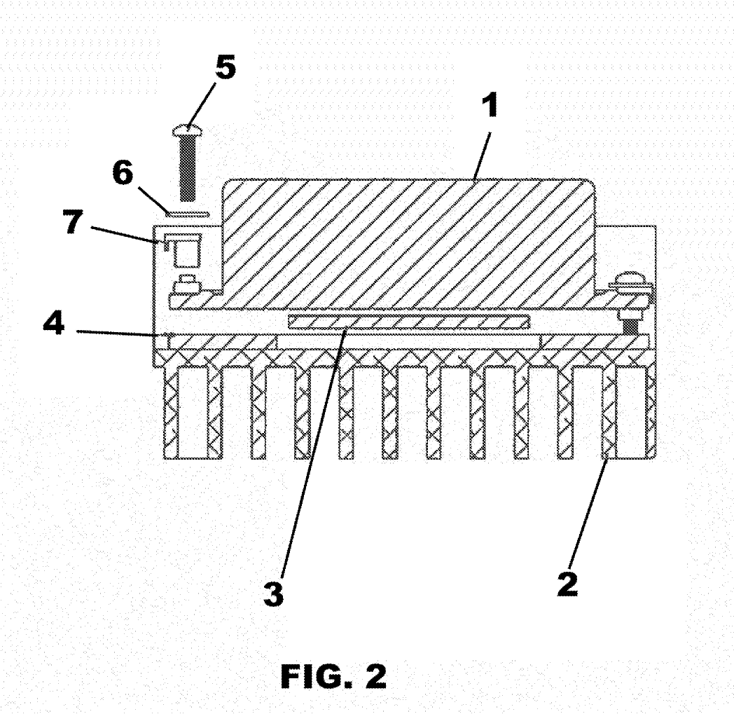

FIGS. 1 and 2 display an embodiment of the invention. FIG. 1 displays an embodiment once fully constructed, while FIG. 2 displays an exploded disassembled version of this embodiment. The electrical device 1 is connected to a rigid base 2 by one or more fasteners 5. A shock absorbing layer is situated between the device 1 and the rigid base 2. The shock absorbing layer is made up of a peripheral gasket 4 and a thermal conductive layer 3. The peripheral gasket 4 is made of closed cell polyurethane foam or any other material with similar characteristics. The peripheral gasket 4 provides shock absorption and helps to minimize the trauma to the electrical device 1. In one embodiment, the type of closed cell polyurethane foam used is PORON. The thermal conductive layer 3 provides both thermal conductivity and additional shock absorption to the assembly.

The electrical device 1, rigid base 2 and shock absorbing layer are kept in position by a fastener assembly consisting of a fastener 5, a washer 6, and a fastening sleeve 7. One or more fastener assemblies may be used to keep the electrical device 1, rigid base 2 and shock absorbing layer in position. The fastener 5 may be conveyed through the washer 6 and subsequently through the fastening sleeve 7 to form the fastener assembly.

The electrical device 1 may be a computer, display screen, touch screen or any other device that may need protection from shock trauma and heat. In a preferred embodiment, the rigid base 2 may be a heatsink.

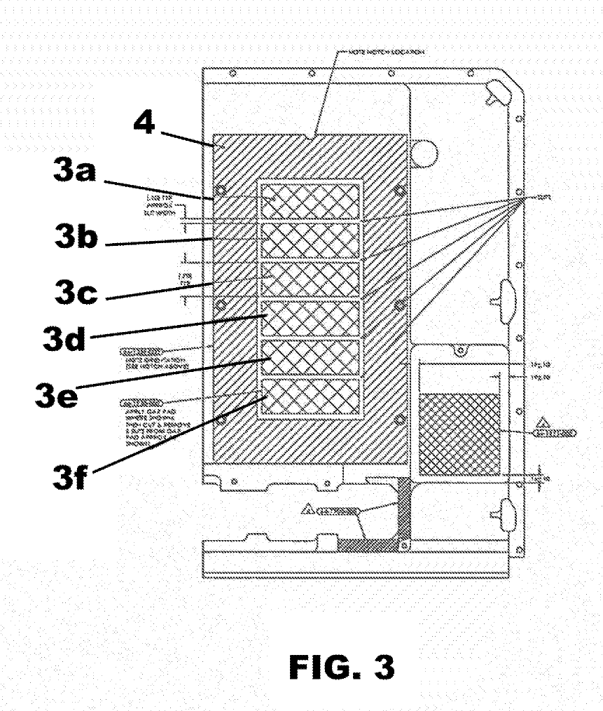

FIG. 3 shows a layout of the peripheral gasket 4 and the thermal conductive layer 3 in one embodiment of the invention. In this embodiment, the thermal conductive layer is configured in multiple rectangular strips 3 (a-f). The thermal conductive strips 3 (a-f) do not abut each other, nor do they abut the peripheral gasket 4. There is space left between each strip 3 (a-f) to allow the strips 3 (a-f) to compress when force is applied due to shock trauma or any other force that would require further compression of the strips 3 (a-f). When the shock trauma is relieved, the strips 3 (a-f) will return to their original shapes and will continue to have a space between them. The strips 3 (a-f) are made of a thermal conductive material to allow for the absorption of heat to protect the electronic device 1 from overheating due to heat created by the shock trauma. In alternate embodiments, the strips 3 (a-f) may take on other shapes and/or configurations. Additionally, it is possible to configure the strips 3 (a-f) to abut each other and/or the peripheral gasket 4.

Both the peripheral gasket 4 and the thermal conductive layer strips 3 (a-f) may be compressed through the fastener assembly(ies), prior to the application of any outside forces. In a preferred embodiment, the peripheral gasket is 0.125 inches thick and is compressed approximately 25%. In the same embodiment, the thermal conductive layer is 0.110 inches thick and is compressed approximately 15%.

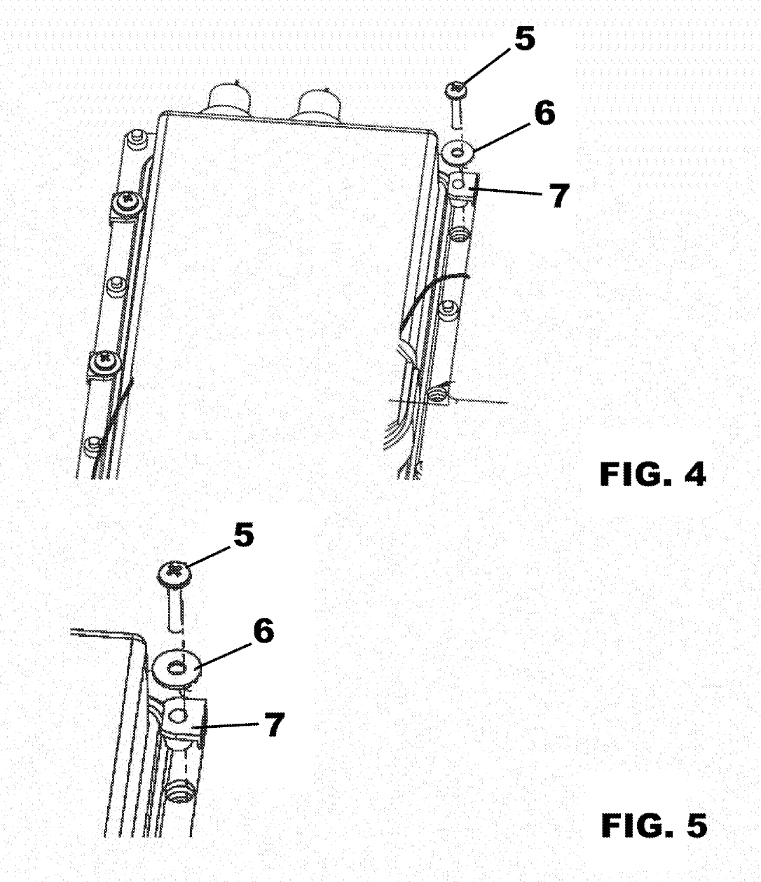

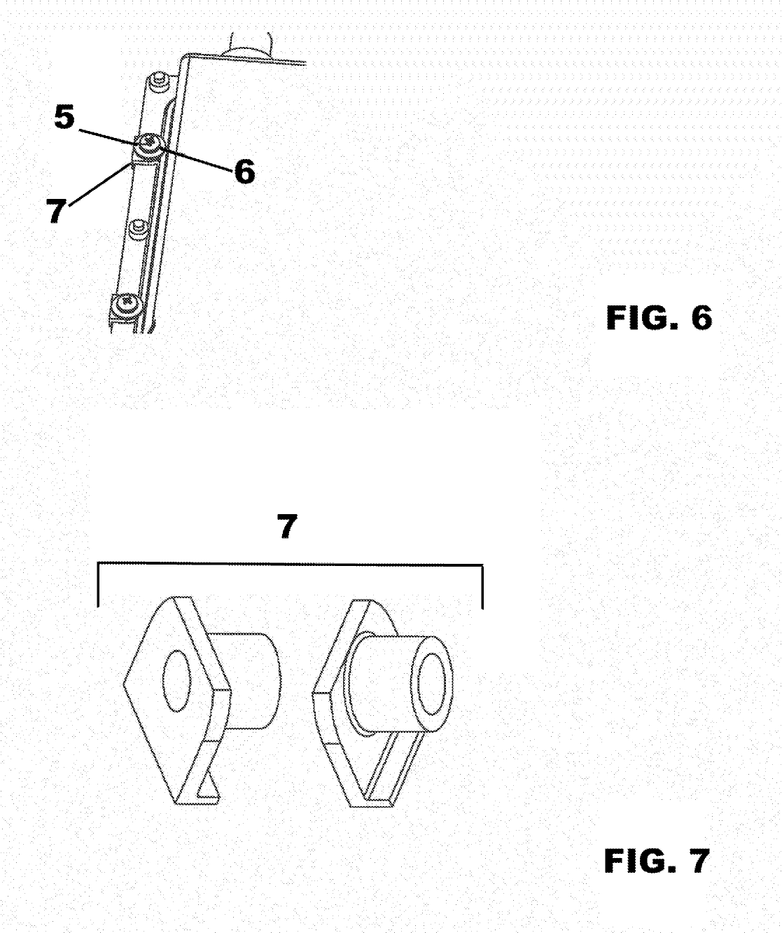

An isolated examination of the fastener assembly can be seen in FIGS. 4-6, showing an exploded view and a completed view of the fastener assembly.

FIG. 7 shows an isolated view of the fastening sleeve 7. The fastening sleeve 7 should have characteristics that allow it to permit slight deformation in compression and shear when force is applied, but also allow for the fastening sleeve 7 to return to its original state after the force is removed. The fastening sleeve should have high stiffness, low friction and excellent dimensional stability. In some embodiments, the fastening sleeve 7 may be made from acetal, polyacetal, polyformaldehyde and/or a polyoxywethylene (POM) such as Delrin.

Any reference in this specification to “one embodiment,” “an embodiment,” example embodiment,” etc., means that a particular feature, structure, or characteristic described in connection with the embodiment is included in at least one embodiment of the invention. The appearances of such phrases in various places in the specification are not necessarily all referring to the same embodiment. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

It should be understood that the examples and embodiments described herein are for illustrative purposes only and that various modifications or changes in light thereof will be suggested to persons skilled in the art and are to be included within the spirit and purview of this application.

1. An assembly comprising:
an electrical device;
a rigid base;
a shock absorbing layer;
said shock absorbing layer comprising:
a peripheral gasket; and
a thermal conductive layer;
wherein said peripheral gasket surrounds said thermal conductive layer;
wherein said peripheral gasket is precompressed;
said shock absorbing layer is positioned between the rigid base and the electrical device;
the electrical device, rigid base, and shock absorbing layer are connected by one or more fastener assemblies;
said one or more fastener assemblies comprising:
a fastener;
a washer; and
a sleeve;
wherein said fastener is conveyed through said washer and into said sleeve.

2. The assembly of claim 1, wherein said thermal conductive layer is comprised of at least one strip of thermal conductive material.

3. The assembly of claim 1, wherein said sleeve is made from a stiff material from the group consisting of acetal, polyacetal, polyformaldehyde or polyoxymethilene.

4. The assembly of claim 1, wherein said sleeve is made from a high stiffness, low friction material.

5. The assembly of claim 1, wherein said fastener assembly allows slight deformation.

6. The assembly of claim 1, wherein said peripheral gasket is made from a closed cell polyurethane foam.

7. The assembly of claim 1, wherein said rigid base is a heat sink.

8. (canceled)

9. (canceled)

10. The assembly of claim 1, wherein said thermal conductive layer is precompressed

11. The assembly of claim 1, wherein said thermal conductive layer does not abut said peripheral gasket.

12. The assembly of claim 1, wherein the thickness of the peripheral gasket is 0.125 inches.

13. The assembly of claim 12, wherein the thickness of the thermal conductive layer is 0.110 inches.

14. The assembly of claim 1, wherein the thickness of the thermal conductive layer is 0.110 inches.

15. The assembly of claim 1, wherein the peripheral gasket is precompressed approximately 25%.

16. The assembly of claim 10, wherein the peripheral gasket is precompressed approximately 25%.

17. The assembly of claim 10, wherein the thermal conductive layer is precompressed approximately 15%.

18. The assembly of claim 16, wherein the thermal conductive layer is precompressed approximately 15%.

19. The assembly of claim 1, wherein the thermal conductive layer is comprised of two or more strips of thermal conductive material.

20. The assembly of claim 19, wherein the two or more strips of thermal conductive material are separated by an interstitial space.
